(19) United States
(12) Patent Application Publication
(10) Pub. No.: US 2025/0374588 A1
(43) Pub. Date: Dec. 4, 2025

(54) SEMICONDUCTOR DEVICE WITH EPITAXIAL LIGHTLY DOPED PORTION AND METHOD FOR FABRICATING THE SAME

(71) Applicant: NANYA TECHNOLOGY CORPORATION, NEW TAIPEI CITY (TW)

(72) Inventor: WEI-CHIH WANG, NEW TAIPEI CITY (TW)

(21) Appl. No.: 18/743,397

(22) Filed: Jun. 14, 2024

Related U.S. Application Data
(62) Division of application No. 18/678,411, filed on May 30, 2024.

(51) Int. Cl. H01L 29/78; H01L 29/423; H01L 29/66

(52) U.S. Cl. CPC H10D 30/601; H10D 64/018; H10D 64/514; H10D 30/0227

(57) ABSTRACT

The present application discloses a semiconductor device and a method for fabricating the semiconductor device. The semiconductor device includes a substrate; a plurality of recesses recessed from a top surface of the substrate defining a channel region between the plurality of recesses and adjacent to the top surface of the substrate; a gate structure positioned on the channel region; a plurality of impurity regions including a plurality of lightly doped portions positioned within the substrate and separated from each other with the channel region in between, and a plurality of bulk doped portions positioned within the substrate, and respectively and correspondingly connected to the plurality of lightly doped portions. A ratio of a thickness of the gate structure to a maximal depth between the top surface of the substrate and a top surface of the plurality of lightly doped portions is between about 7.00 and about 3.60.

### CROSS-REFERENCE TO RELATED APPLICATION

This application is a divisional application of U.S. Non-Provisional application Ser. No. 18/678,411 filed May 30, 2024, which is incorporated herein by reference in its entirety.

### TECHNICAL FIELD

The present disclosure relates to a semiconductor device and a method for fabricating the semiconductor device, and more particularly, to a semiconductor device with an epitaxial lightly doped portion and a method for fabricating the semiconductor device with an epitaxial lightly doped portion.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a plurality of recesses recessed from a top surface of the substrate defining a channel region between the plurality of recesses and adjacent to the top surface of the substrate; a gate structure positioned on the channel region; a plurality of impurity regions including a plurality of lightly doped portions positioned within the substrate and separated from each other with the channel region in between, and a plurality of bulk doped portions positioned within the substrate, and respectively and correspondingly connected to the plurality of lightly doped portions. A ratio of a thickness of the gate structure to a maximal depth between the top surface of the substrate and a top surface of the plurality of lightly doped portions is between about 7.00 and about 3.60.

Another aspect of the present disclosure provides a semiconductor device including a substrate including a bottom semiconductor layer, a buried insulating layer positioned on the bottom semiconductor layer, and a top semiconductor layer positioned on the buried insulating layer; a plurality of recesses recessed from a top surface of the top semiconductor layer defining a channel region between the plurality of recesses and adjacent to the top surface of the top semiconductor layer; a gate structure positioned on the channel region; a plurality of impurity regions including a plurality of lightly doped portions positioned within the top semiconductor layer and separated from each other with the channel region in between, and a plurality of bulk doped portions positioned within the top semiconductor layer, and respectively and correspondingly connected to the plurality of lightly doped portions. A ratio of a thickness of the gate structure to a maximal depth between the top surface of the substrate and a top surface of the plurality of lightly doped portions is between about 7.00 and about 3.60.

Another aspect of the present disclosure provides a method for fabricating a semiconductor device including providing a substrate; forming a gate structure on the substrate and forming an inner spacer layer covering the gate structure; recessing the substrate to form a plurality of recesses separated from each other with the gate structure in between; forming a plurality of epitaxial layers within the plurality of recesses; forming a middle spacer layer covering the inner spacer layer and masking portions of the plurality of epitaxial layers; partially removing the plurality of epitaxial layers to form a plurality of precursive layers and exposing the substrate; forming a plurality of pre-impurity regions in the substrate and connecting to the plurality of precursive layers; and performing a thermal treatment to turn the plurality of precursive layers into a plurality of lightly doped portions and the plurality of pre-impurity regions into a plurality of bulk doped portions. The plurality of lightly doped portions and the plurality of bulk doped portions together configure a plurality of impurity regions.

Due to the design of the semiconductor device of the present disclosure, the drain-induced barrier lowering (DIBL) may be reduced by the employment of the plurality of lightly doped portions formed by epitaxial growth with tailored dopant concentration and the recessing of substrate. This mitigation may lead to enhanced on/off ratio and reduced random dopant fluctuations, resulting in enhanced performance of semiconductor device.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIGS. 2 to 14 illustrate, in schematic cross-sectional view diagrams, a flow for fabricating the semiconductor device in accordance with one embodiment of the present disclosure;

FIGS. 15 and 16 illustrate, in schematic cross-sectional view diagrams, semiconductor devices in accordance with some embodiments of the present disclosure;

FIGS. 17 to 29 illustrate, in schematic cross-sectional view diagrams, a flow for fabricating the semiconductor device in accordance with another embodiment of the present disclosure; and

FIG. 30 illustrates, in a schematic cross-sectional view diagram, a semiconductor device 1E in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

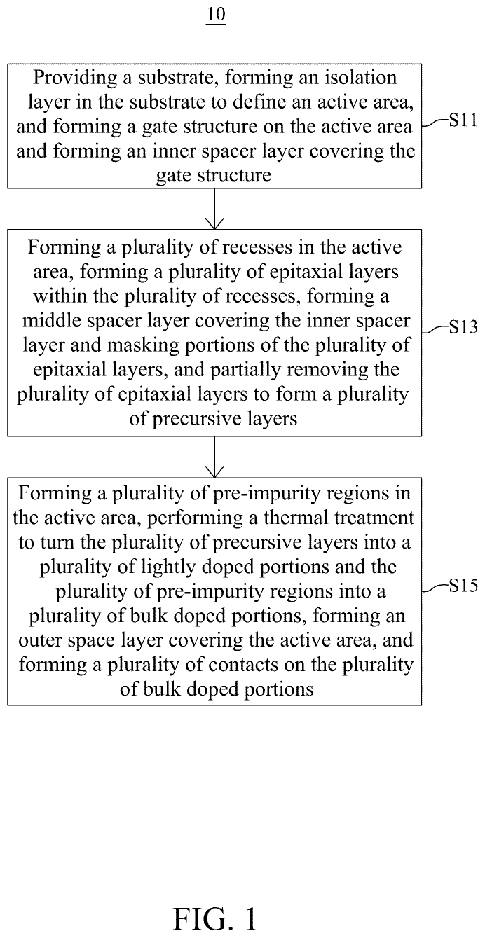

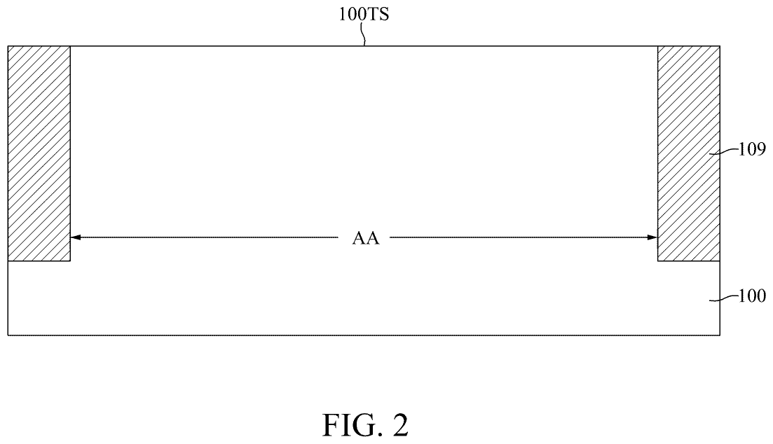

FIG. 1 illustrates, in a flowchart diagram form, a method 10 for fabricating a semiconductor device 1A in accordance with one embodiment of the present disclosure. FIGS. 2 to 14 illustrate, in schematic cross-sectional view diagrams, a flow for fabricating the semiconductor device 1A in accordance with one embodiment of the present disclosure.

With reference to FIGS. 1 to 6, at step S11, a substrate 100 may be provided, an isolation layer 109 may be formed in the substrate 100 to define an active area AA, and a gate structure 200 may be formed on the active area AA and an inner spacer layer 401 may be formed covering the gate structure 200.

With reference to FIG. 2, the substrate 100 may be a bulk semiconductor substrate that is composed entirely of at least one semiconductor material; the bulk semiconductor substrate does not contain any dielectrics, insulating layers, or conductive features. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof.

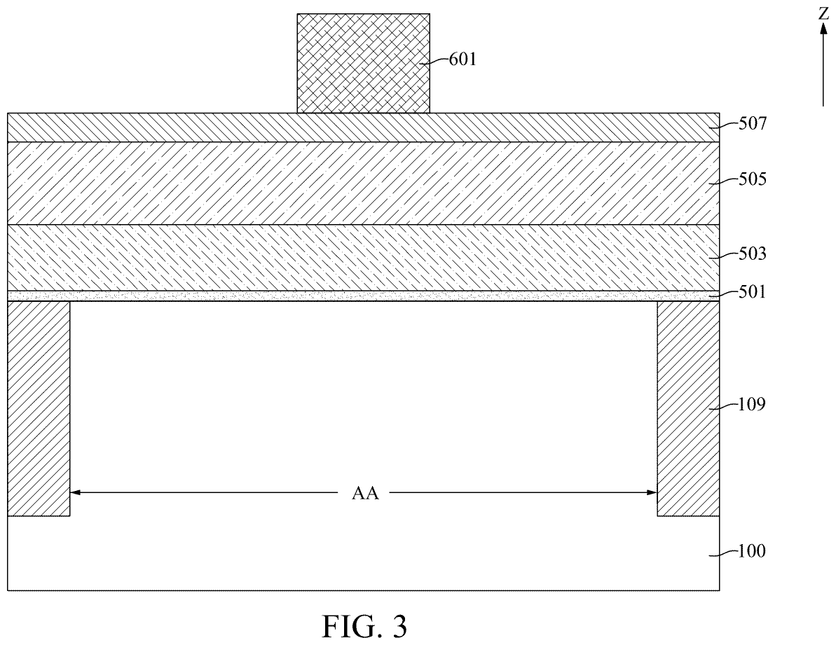

With reference to FIGS. 2 and 3, the isolation layer 109 may be formed in the substrate 100. A series of deposition processes may be performed to deposit a pad oxide layer (not shown) and a pad nitride layer (not shown) on the substrate 100. A photolithography process and a subsequent etching process, such as an anisotropic dry etching process, may be performed to form trenches penetrating through the pad oxide layer, the pad nitride layer, and extending to the substrate 100. An insulating material may be deposited into the trenches and a planarization process, such as chemical mechanical polishing, may be subsequently performed until the top surface 100TS of the substrate 100 is exposed to remove excess filling material, provide a substantially flat surface for subsequent processing steps, and concurrently form the isolation layer 109. The insulating material may be, for example, silicon oxide or other applicable insulating materials. The isolation layer 109 may define the active area AA in the substrate 100.

It should be noted that, in the description of the present disclosure, a surface of an element (or a feature) located at the highest vertical level along the Z axis is referred to as a top surface of the element (or the feature). A surface of an element (or a feature) located at the lowest vertical level along the Z axis is referred to as a bottom surface of the element (or the feature).

It should be noted that the active area AA may comprise a portion of the substrate 100 and a space above the portion of the substrate 100. Describing an element as being disposed on the active area AA means that the element is disposed on a top surface 100TS of the portion of the substrate 100. Describing an element as being disposed in (or within) the active area AA means that the element is disposed in the portion of the substrate 100; however, a top surface of the element may be even or coplanar with the top surface 100TS of the portion of the substrate 100. Describing an element as being disposed above the active area AA means that the element is disposed above the top surface 100TS of the portion of the substrate 100.

With reference to FIG. 3, a layer of first insulating material 501 may be formed on the substrate 100 and covering the active area AA. In some embodiments, the first insulating material 501 may include, for example, a high-k material, silicon oxide, or combinations thereof. In some embodiments, the layer of first insulating material 501 may be formed by, for example, chemical vapor deposition, atomic layer deposition, or other applicable deposition processes.

In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide or a combination thereof.

With reference to FIG. 3, a layer of first conductive material 503 may be formed on the layer of first insulating material 501. In some embodiments, the first conductive material 503 may include, for example, doped polycrystalline silicon, doped polycrystalline germanium, doped polycrystalline silicon germanium, or a combination thereof. In some embodiments, the layer of first conductive material 503 may be doped by n-type dopants or p-type dopants. The n-type dopants may include, for example, antimony, arsenic, and phosphorus. The p-type dopants may include, for example, boron, aluminum, gallium, and indium. In some embodiments, the layer of first conductive material 503 may be formed by, for example, chemical vapor deposition, plasma-enhanced chemical vapor deposition, or other applicable deposition processes.

With reference to FIG. 3, a layer of second conductive material 505 may be formed on the layer of first conductive material 503. In some embodiments, the second conductive material 505 may include, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the layer of second conductive material 505 may be formed by, for example, physical vapor deposition, sputtering, electroplating, electroless plating, chemical vapor deposition, atomic layer deposition, or other applicable deposition processes.

With reference to FIG. 3, a layer of second insulating material 507 may be formed on the layer of second conductive material 505. In some embodiments, the second insulating material 507 may include, for example, an oxide, a nitride, or an oxynitride. In some embodiments, the second insulating material 507 may include silicon nitride or silicon oxide. In some embodiments, the layer of second insulating material 507 may be formed by, for example, chemical vapor deposition or other applicable deposition processes.

With reference to FIG. 3, a first mask layer 601 may be formed on the layer of second insulating material 507. In some embodiments, the first mask layer 601 may be a photoresist layer. In some embodiments, the first mask layer 601 may include the pattern of the gate structure 200.

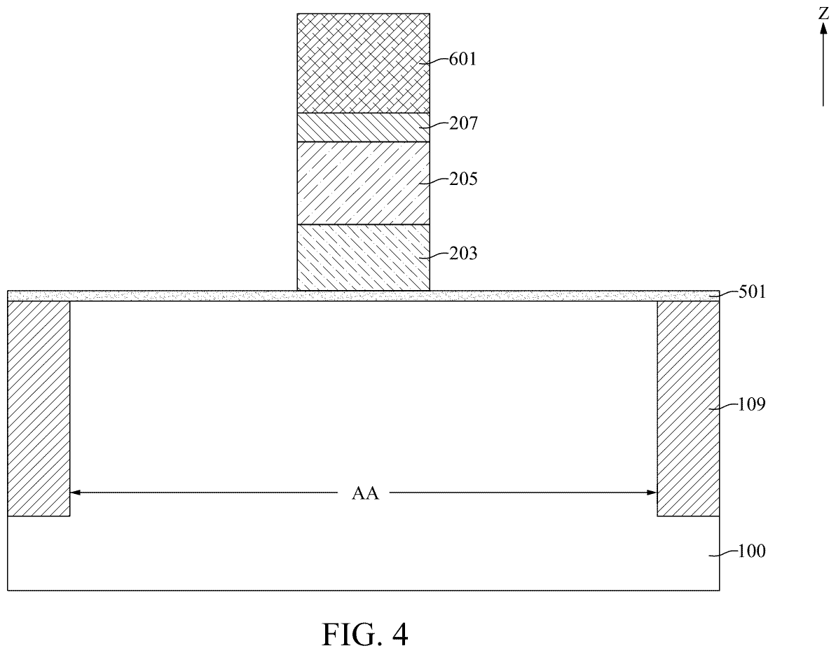

With reference to FIG. 4, an etching process may be performed using the first mask layer 601 as the mask to remove portions of the second insulating material 507, the second conductive material 505, and the first conductive material 503. In some embodiments, the etching process may be an anisotropic dry etching process. The remaining first conductive material 503 may be referred to as a gate bottom conductive layer 203. The gate bottom conductive layer 203 may be disposed on the layer of first insulating material 501. The remaining second conductive material 505 may be referred to as a gate top conductive layer 205. The gate top conductive layer 205 may be disposed on the gate bottom conductive layer 203. The remaining second insulating material 507 may be referred to as a gate capping layer 207. The gate capping layer 207 may be disposed on the gate top conductive layer 205. In some embodiments, the width of the gate capping layer 207, the width of the gate top conductive layer 205, and the width of the gate bottom conductive layer 203 may be substantially the same.

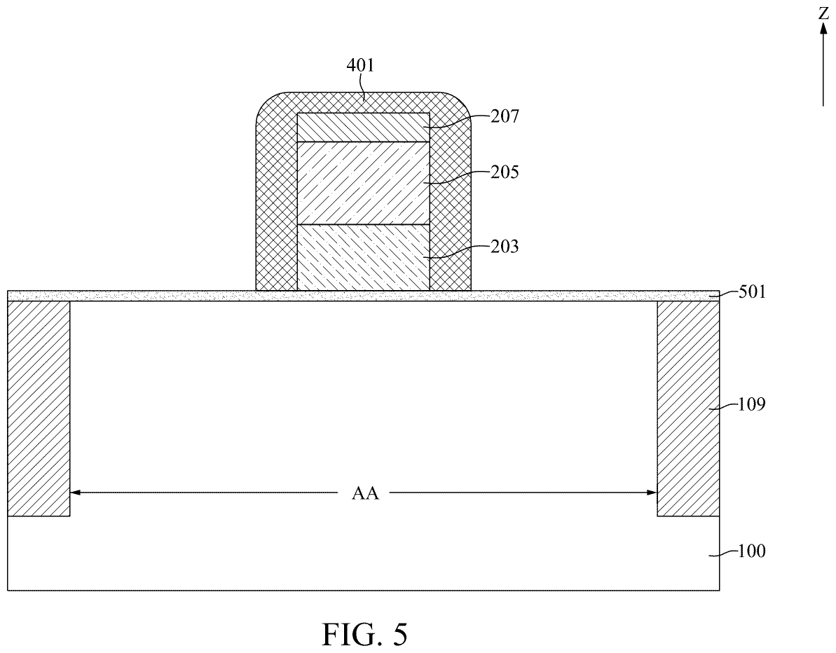

With reference to FIG. 5, the inner spacer layer 401 may be conformally formed to cover the stack of the gate bottom conductive layer 203, the gate top conductive layer 205, and the gate capping layer 207. The inner spacer layer 401 may also cover portions of the layer of first insulating material 501. Stated differently, the inner spacer layer 401 may be formed on the layer of first insulating material 501 and enclose the stack of the gate bottom conductive layer 203, the gate top conductive layer 205, and the gate capping layer 207. In some embodiments, the inner spacer layer 401 may be formed of the same material as the gate capping layer 207. In some embodiments, the inner spacer layer 401 may include, for example, a nitride or an oxynitride. In some embodiments, the inner spacer layer 401 may include silicon nitride, silicon oxynitride, or silicon nitride oxide. In some embodiments, the inner spacer layer 401 may be formed by, for example, chemical vapor deposition or other applicable deposition processes with a subsequent anisotropic etching process.

It should be noted that, in the description of the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

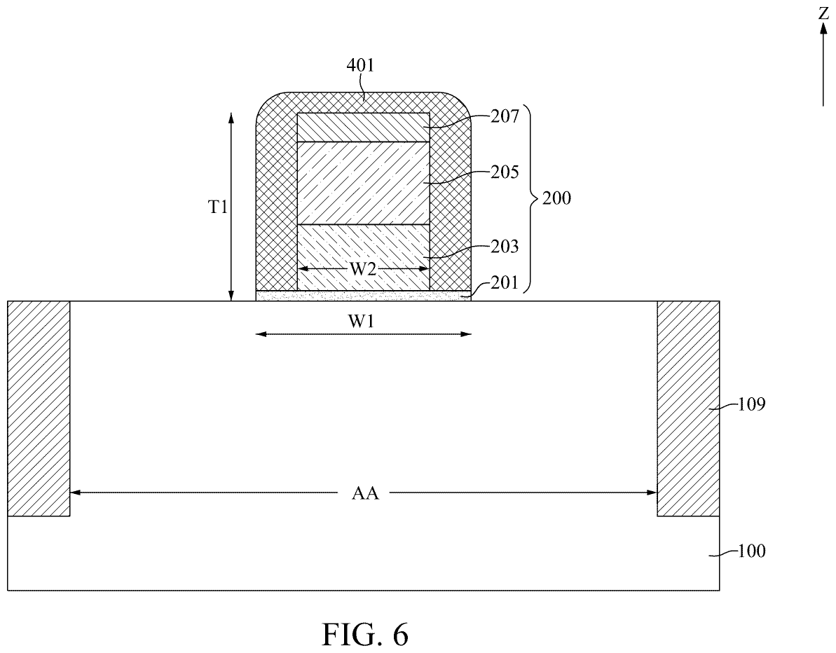

With reference to FIG. 6, an etching process may be performed using the inner spacer layer 401 as the mask to remove portions of the first insulating material 501. In some embodiments, the etching process may be an anisotropic dry etching process. The active area AA may be exposed after the etching process. The remaining first insulating material 501 may be referred to as the gate dielectric layer 201. In some embodiments, the width W1 of the gate dielectric layer 201 may be greater than the width W2 of the gate bottom conductive layer 203. The gate dielectric layer 201, the gate bottom conductive layer 203, the gate top conductive layer 205, and the gate capping layer 207 together configure the gate structure 200. In some embodiments, the thickness T1 of the gate structure 200 may be between about 70 nm and about 55 nm.

With reference to FIG. 1 and FIGS. 7 to 9, at step S13, a plurality of recesses R1 may be formed in the active area AA, a plurality of epitaxial layers 509 may be formed within the plurality of recesses R1, a middle spacer layer 403 may be formed covering the inner spacer layer 401 and masking portions of the plurality of epitaxial layers 509, and the plurality of epitaxial layers 509 may be partially removed to form a plurality of precursive layers 303.

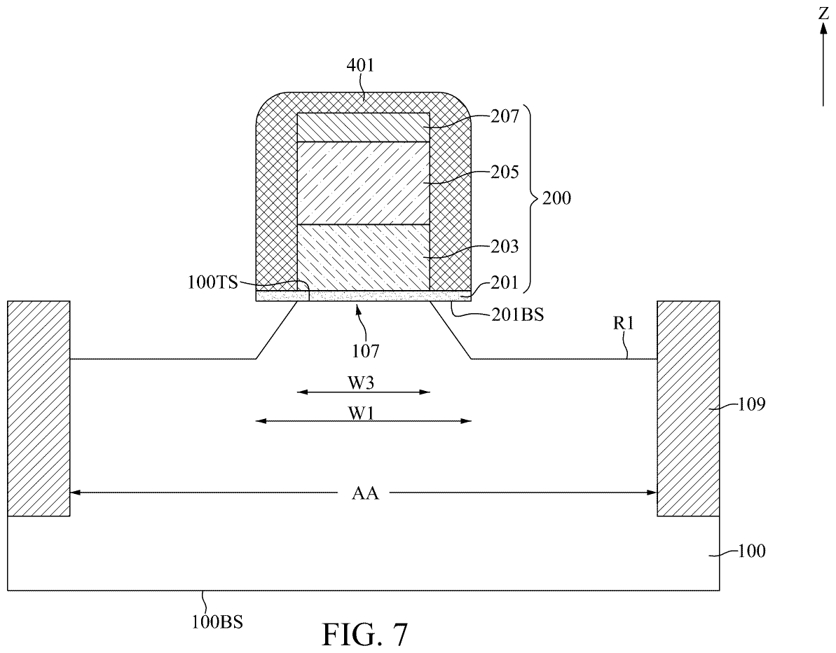

With reference to FIG. 7, an etching process may be performed to recess the active area AA to form the plurality of recesses R1. In some embodiments, the etching process may be an isotropic etching process. In some embodiments, the etching process may be a wet etching process. During the etching process, portions of the active area AA under the gate dielectric layer 201 may also be laterally etched, exposing portions of the bottom surface 201BS of the gate dielectric layer 201 through the plurality of recesses R1. In some embodiments, the plurality of recesses R1 may be formed from the top surface 100TS of the substrate 100 towards the bottom surface 100BS of the substrate 100, separated from each other, and defining a channel region 107. The channel region 107 may be disposed between the plurality of recesses R1 and directly under the gate dielectric layer 201. The width W3 of the channel region 107 may be less than the width W1 of the gate dielectric layer 201.

In some embodiments, the etching process may be a wet etching process including a mixture of nitric acid and hydrofluoric acid. The wet etching process may be initiated by the nitric acid, which forms a layer of silicon dioxide on the silicon (i.e., on the top surface of the active area AA), and the hydrofluoric acid dissolves the silicon oxide away. In some embodiments, water may be used to dilute the etchant, with acetic acid used as a buffering agent.

In some embodiments, a pre-clean process may be performed before the recessing of the plurality of recesses R1. The pre-clean process may include exposing the active area AA to a solution including a fluoride component, an oxidizing agent, and an inorganic acid.

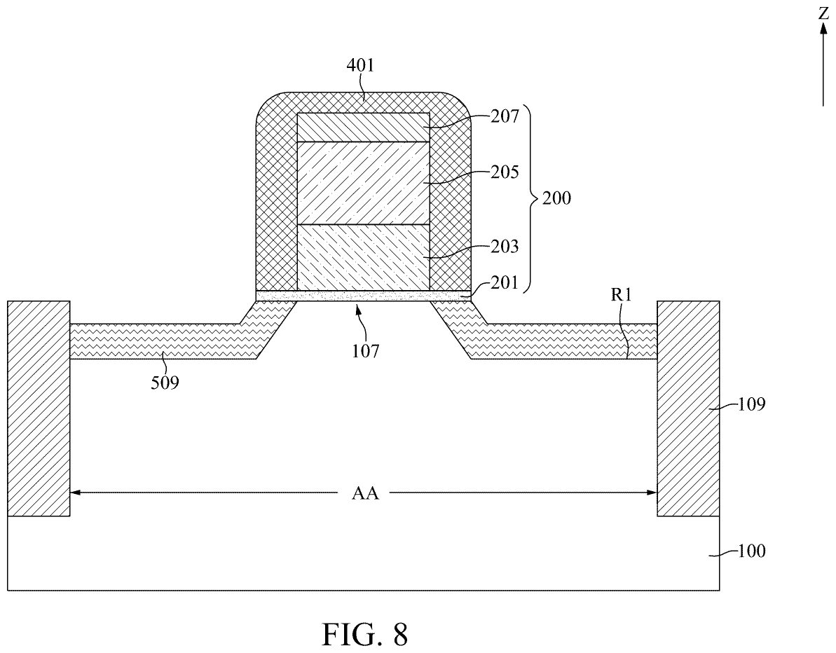

With reference to FIG. 8, the plurality of epitaxial layers 509 may be conformally formed on the active area AA and within the plurality of recesses R1. In some embodiments, the plurality of epitaxial layers 509 may include, for example, silicon, germanium, or silicon germanium. In some embodiments, the plurality of epitaxial layers 509 may be doped with n-type dopants or p-type dopants. In some embodiments, the dopant concentration of the plurality of epitaxial layers 509 may be between about 2E20 atoms/cm³ and about 4E20 atoms/cm³, or about 3E20 atoms/cm³. In some embodiments, the electrical type of the plurality of epitaxial layers 509 may be n-type or p-type, depending on the dopants doped during the formation of the plurality of epitaxial layers 509.

In some embodiments, the plurality of epitaxial layers 509 may be grown by exposing the active area AA to a radio frequency plasma from a gas flow including an etching gas. In some embodiments, the etching gas may include a halogen. In some embodiments, the etching gas may include tetrafluorosilane. In some embodiments, the flow rate of the gas flow may be between about 30 standard cubic centimeters per minute (sccm) and about 40 sccm. In some embodiments, the radio frequency power of the radio frequency plasma may be between about 300 W and about 450 W. In some embodiments, the exposure of the radio frequency plasma may be between about 1 second and about 2 minutes.

In some embodiments, the plurality of epitaxial layers 509 may be formed by a deposition process that includes exposing the active area AA to a deposition gas containing at least a silicon source and a carrier gas. The deposition gas may also include a dopant source.

Detailedly, the deposition process may begin by adjusting the process chamber containing the intermediate semiconductor device illustrated in FIG. 7 to a predetermined temperature and pressure. The temperature may be tailored to the particular conducted process. In some embodiments, the process chamber may be kept at a temperature in the range from about 250° C. to about 1000° C., from about 500° C. to about 800° C., or from about 550° C. to about 750° C. The appropriate temperature to conduct the deposition process may depend on the particular precursors used to deposit the plurality of epitaxial layers 509. In some embodiments, the process chamber may be usually maintained at a pressure from about 0.1 Torr to about 200 Torr, or from about 1 Torr to about 50 Torr. The pressure may fluctuate during the deposition process but may be generally maintained constant.

After the process chamber is tuned to the appropriate temperature and pressure, the intermediate semiconductor device illustrated in FIG. 7 may be exposed to the deposition gas containing the silicon source and the carrier gas to form the plurality of epitaxial layers 509. In some embodiments, the active area AA may be exposed to the deposition gas for a period of time of about 0.5 seconds to about 30 seconds, from about 1 second to about 20 seconds, or from about 5 seconds to about 10 seconds. The specific exposure time of the deposition process may be determined in relation to the particular precursors, temperature, and pressure used in the deposition process.

In some embodiments, the deposition gas for depositing the plurality of epitaxial layers 509 may include at least the silicon source and the carrier gas. In some embodiments, the deposition gas may further include a dopant compound to provide a source of dopants, such as boron, arsenic, phosphorus, gallium and/or aluminum.

In some embodiments, the silicon source may be usually provided into the process chamber at a rate in a range from about 5 sccm to about 500 sccm, from about 10 sccm to about 300 sccm, or from about 50 sccm to about 200 sccm. For example, the silicon source may be provided into the process chamber at a rate about 100 sccm.

In some embodiments, the silicon source may include silanes, halogenated silanes, and/or organosilanes.

In some embodiments, silanes may include silane (SiH₄) and higher silanes with the empirical formula SiₓH₍₂ₓ₊₂₎, such as disilane (Si₂H₆), trisilane (Si₃H₈), and tetrasilane (Si₄H₁₀), as well as others.

In some embodiments, halogenated silanes may include compounds with the empirical formula X′_{y}SiₓH_{(2x+2-y)}, where X′ is F, Cl, Br or I, such as hexachlorodisilane (Si₂Cl₆), tetrachlorosilane (SiCl₄), dichlorosilane (Cl₂SiH₂), and trichlorosilane (Cl₃SiH).

In some embodiments, organosilanes may include compounds with the empirical formula R_{y}SiₓH_{(2x+2-y)}, where R is methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyidisilane ((CH₃)₂Si₂H₄), and hexamethyldisilane ((CH₃)₆Si₂).

In the present embodiment, the silicon source may include silane, dichlorosilane, and disilane.

The silicon source may be provided into the process chamber along with the carrier gas. In some embodiments, the carrier gas may have a flow rate from about 1 slm (standard liters per minute) to about 100 slm, from about 5 slm to about 75 slm, or from about 10 slm to about 50 slm. In the present embodiment, the flow rate of the carrier gas may be, for example, about 25 slm.

The carrier gas may be selected based on the precursor (e.g., the silicon source) used and/or the process temperature during the deposition process. Usually, the carrier gas may be the same throughout the deposition process. However, some embodiments may use different carrier gases during the deposition process.

In some embodiments, the carrier gas may include nitrogen, hydrogen, argon, helium, or a combination thereof. In some embodiments, an inert carrier gas may be preferred and include nitrogen, argon, helium, and a combination thereof.

In some embodiments, nitrogen may be utilized as the carrier gas in embodiments featuring low temperature (e.g., <800° C.) processes. Nitrogen remains inert during low temperature deposition processes. Therefore, nitrogen is not incorporated into the plurality of epitaxial layers 509 during low temperature deposition processes. Also, a nitrogen carrier gas does not form hydrogen-terminated surfaces as does a hydrogen carrier gas. The hydrogen-terminated surfaces formed by the adsorption of hydrogen carrier gas on the surface inhibit the growth rate of the plurality of epitaxial layers 509. Finally, the low temperature processes may take economic advantage of nitrogen as a carrier gas, since nitrogen is far less expensive than hydrogen, argon or helium.

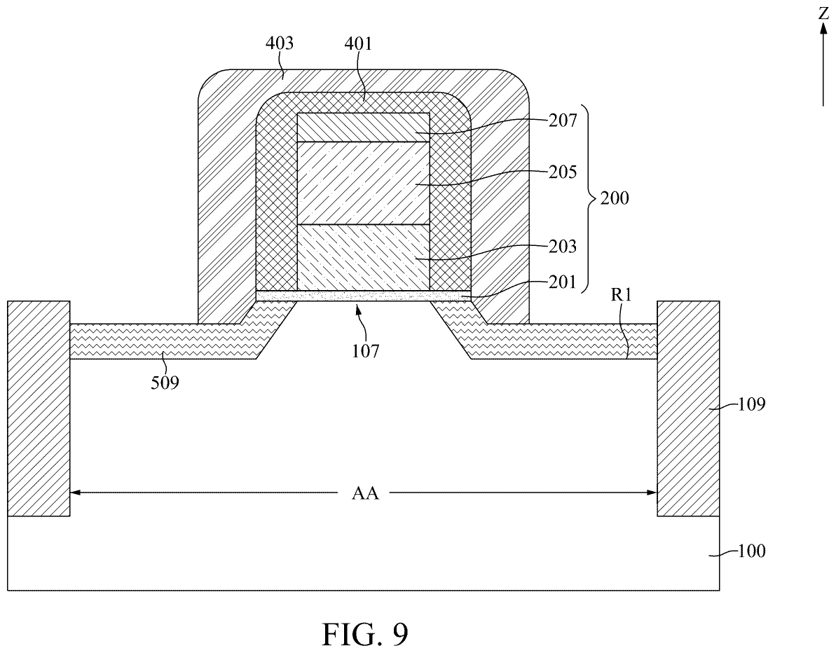

With reference to FIG. 9, a middle spacer layer 403 may be conformally formed to cover the inner spacer layer 401. The middle spacer layer 403 may also cover portions of the plurality of epitaxial layers 509. Stated differently, the middle spacer layer 403 may be formed on the plurality of epitaxial layers 509 and enclose the inner spacer layer 401. In some embodiments, the middle spacer layer 403 may be formed of a material having etching selectivity to the inner spacer layer 401. In some embodiments, the middle spacer layer 403 may be formed of, for example, silicon oxide. In some embodiments, the middle spacer layer 403 may be formed by, for example, chemical vapor deposition or other applicable deposition processes with a subsequent anisotropic etching process.

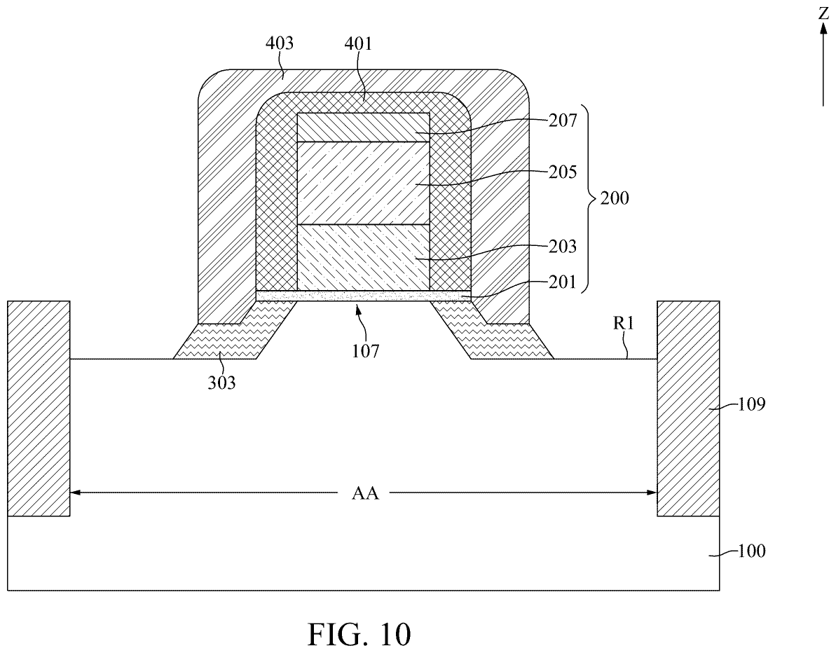

With reference to FIG. 10, an etching process may be performed using the middle spacer layer 403 as the mask to remove portions of the plurality of epitaxial layers 509. During the etching process, the plurality of epitaxial layers 509 may be exposed to the etching gas for a period of time in the range from about 10 seconds to about 90 seconds, from about 20 seconds to about 60 seconds, or from about 30 seconds to about 45 seconds. After the etching process, the remaining epitaxial layers 509 may be referred to as the plurality of precursive layers 303. The plurality of precursive layers 303 may have the same electrical type as the plurality of epitaxial layers 509.

In some embodiments, the etching gas may include at least one etchant and a carrier gas. The etchant may be provided into the process chamber at a rate in the range from about 10 sccm to about 700 sccm, from about 50 sccm to about 500 sccm, or from about 100 sccm to about 400 sccm. For example, the flow rate of the etchant may be at about 200 sccm.

The etchant used in the etching gas may include chlorine, hydrogen chloride, boron trichloride, carbon tetrachloride, chlorotrifluoride, or a combination thereof.

The etchant may be usually provided into the process chamber with the carrier gas. The carrier gas may have a flow rate in the range from about 1 slm to about 100 slm, from about 5 slm to about 75 slm, or from about 10 slm to about 50 slm. For example, the flow rate of the carrier gas may be about 25 slm. In some embodiments, the carrier gas may include nitrogen, hydrogen, argon, helium, or a combination thereof.

In some embodiments, an inert carrier gas is preferred and includes nitrogen, argon, helium and combinations thereof. The carrier gas may be selected based upon specific precursor(s) and/or temperature used during the deposition of the plurality of epitaxial layers 509. The same carrier gas may be usually used during the deposition of the plurality of epitaxial layers 509 and the subsequent etching process. However, in some embodiments, different carrier gasses may be applied during the deposition of the plurality of epitaxial layers 509 and the subsequent etching process.

In some embodiments, the preferred etchant may be chlorine gas, especially when the deposition process of the plurality of epitaxial layers 509 is conducted at a low temperature (e.g., <800° C.). For example, the etching process using an etching gas containing chlorine as the etchant and nitrogen as the carrier gas may be performed at a temperature in a range from about 500° C. to about 750° C. In another example, the etching process using an etching gas containing chlorine and nitrogen may be performed at a temperature in a range from about 250° C. to about 500° C.

With reference to FIG. 1 and FIGS. 11 to 14, at step S15, a plurality of pre-impurity regions 511 may be formed in the active area

AA, a thermal treatment may be performed to turn the plurality of precursive layers 303 into a plurality of lightly doped portions 301-1 and the plurality of pre-impurity regions 511 into a plurality of bulk doped portions 301-3, an outer space layer 405 may be formed covering the active area AA, and a plurality of contacts 111 may be formed on the plurality of bulk doped portions 301-3.

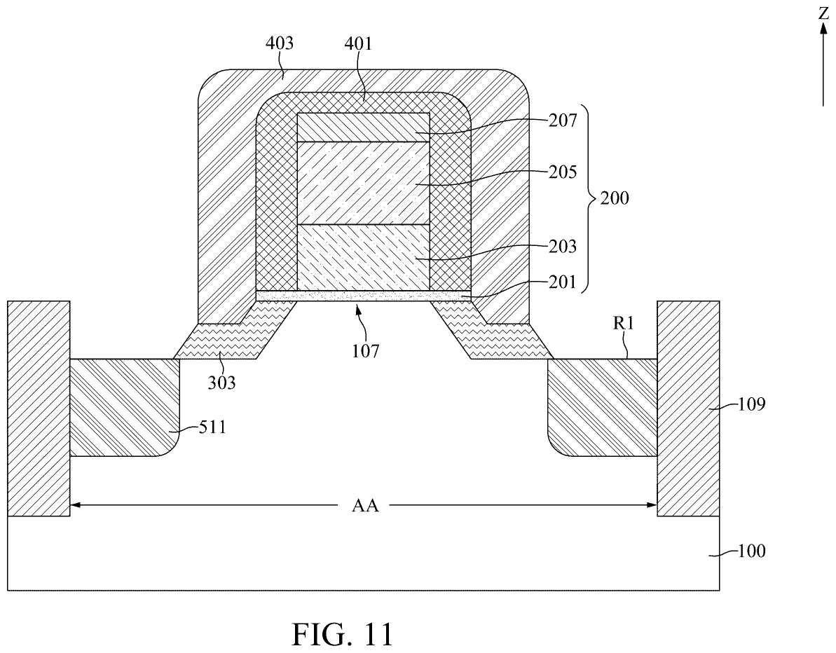

With reference to FIG. 11, an implantation process may be performed to form the plurality of pre-impurity regions 511 in the active area AA. In some embodiments, the plurality of pre-impurity regions 511 may include n-type dopants or p-type dopants. In some embodiments, the electrical type of the plurality of pre-impurity regions 511 may have the same electrical type as the plurality of precursive layers 303. The plurality of pre-impurity regions 511 may be disposed adjacent to the plurality of precursive layers 303, respectively and correspondingly.

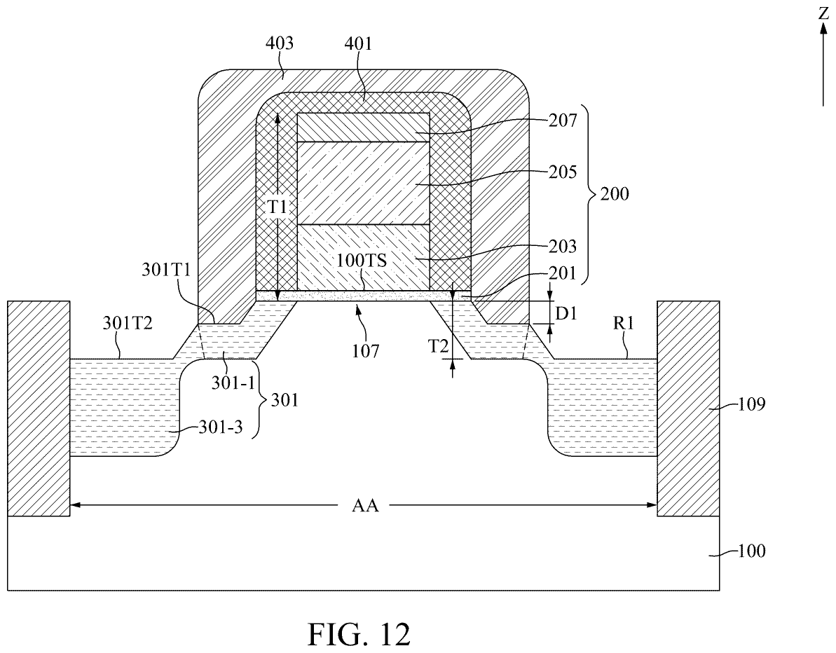

With reference to FIG. 12, the thermal treatment may be performed to activate the plurality of precursive layers 303 and the plurality of pre-impurity regions 511. In some embodiments, the temperature of the thermal treatment may be between about 800° C. and about 1250° C. In some embodiments, the thermal treatment may have a process duration between about 1 millisecond and about 500 milliseconds. In some embodiments, the thermal treatment may include, for example, a rapid thermal anneal, a laser spike anneal, or a flash lamp anneal.

After the thermal treatment, the plurality of precursive layers 303 may be turned into the plurality of lightly doped portions 301-1 and the plurality of pre-impurity regions 511 may be turned into the plurality of bulk doped portions 301-3. The plurality of lightly doped portions 301-1 and the plurality of bulk doped portions 301-3 together configure the plurality of impurity regions 301. In some embodiments, during the thermal treatment, the boundaries of the precursive layer 303 and the pre-impurity region 511 may merge and fuse together due to diffusion, forming the impurity region 301. In some embodiments, the dopant concentration of the plurality of lightly doped portions 301-1 may be less than the dopant concentration of the plurality of bulk doped portions 301-3.

In some embodiments, the plurality of lightly doped portions 301-1 may be disposed in the active area AA, and under the middle spacer layer 403 and the gate dielectric layer 201. The channel region 107 may be disposed between the plurality of lightly doped portions 301-1 and under the gate dielectric layer 201. In some embodiments, the thickness T2 of the plurality of lightly doped portions 301-1 may be between about 20 nm and about 25 nm. In some embodiments, the ratio of the thickness T1 of the gate structure 200 to the maximal depth D1 between the top surface 100TS of the substrate 100 and the top surface 301T1 of the plurality of lightly doped portions 301-1 may be between about 7.00 and about 3.60, between about 7.00 and about 4.60, or between about 5.50 and 3.60. In some embodiments, the ratio of the thickness T1 of the gate structure 200 to the thickness T2 of the plurality of lightly doped portions 301-1 may be between about 3.50 and about 2.20, between about 3.50 and about 2.80, or between about 2.80 and about 2.75. In some embodiments, the plurality of bulk doped portions 301-3 may be disposed in the active area AA and connect to the plurality of bulk doped portions 301-3, respectively and correspondingly. The plurality of bulk doped portions 301-3 may be exposed through the plurality of recesses R1. The top surfaces 301T1 of the plurality of lightly doped portions 301-1 and the top surfaces 301T2 of the plurality of bulk doped portions 301-3 may be coplanar with the plurality of recesses R1.

In some embodiments, the thermal treatment may be integrated in the implantation for forming the plurality of pre-impurity regions 511.

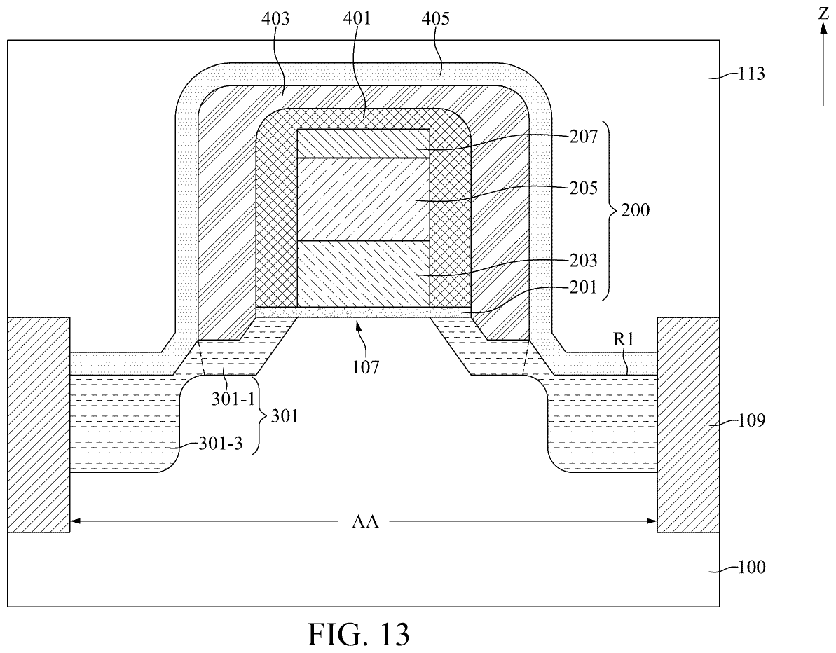

With reference to FIG. 13, the outer space layer 405 may be conformally formed to cover the middle spacer layer 403 and the plurality of bulk doped portions 301-3. Stated differently, the outer space layer 405 may be formed on the plurality of bulk doped portions 301-3 and enclose the middle spacer layer 403. In some embodiments, the outer space layer 405 may be formed of the same material as the inner spacer layer 401. In some embodiments, the outer space layer 405 may include, for example, a nitride or an oxynitride. In some embodiments, the outer space layer 405 may include silicon nitride, silicon oxynitride, or silicon nitride oxide. In some embodiments, the inner spacer layer 401 may be formed by, for example, chemical vapor deposition or other applicable deposition processes with a subsequent anisotropic etching process.

With reference to FIG. 13, a first insulating layer 113 may be formed over the substrate 100 to cover the outer space layer 405 and the isolation layer 109. A planarization process, such as chemical mechanical polishing, may be performed to remove excess material and provide a substantially flat surface for subsequent processing steps. In some embodiments, the first insulating layer 113 may be formed of, for example, silicon oxide, borophosphosilicate glass, undoped silicate glass, fluorinated silicate glass, low-k dielectric materials, or a combination thereof. The low-k dielectric materials may have a dielectric constant less than 3.0 or even less than 2.5. In some embodiments, the undoped silicate glass can be expressed as formula SiOₓ. The x may be between 1.4 and 2.1. In some embodiments, the first insulating layer 113 may be formed by, for example, chemical vapor deposition or other applicable deposition processes.

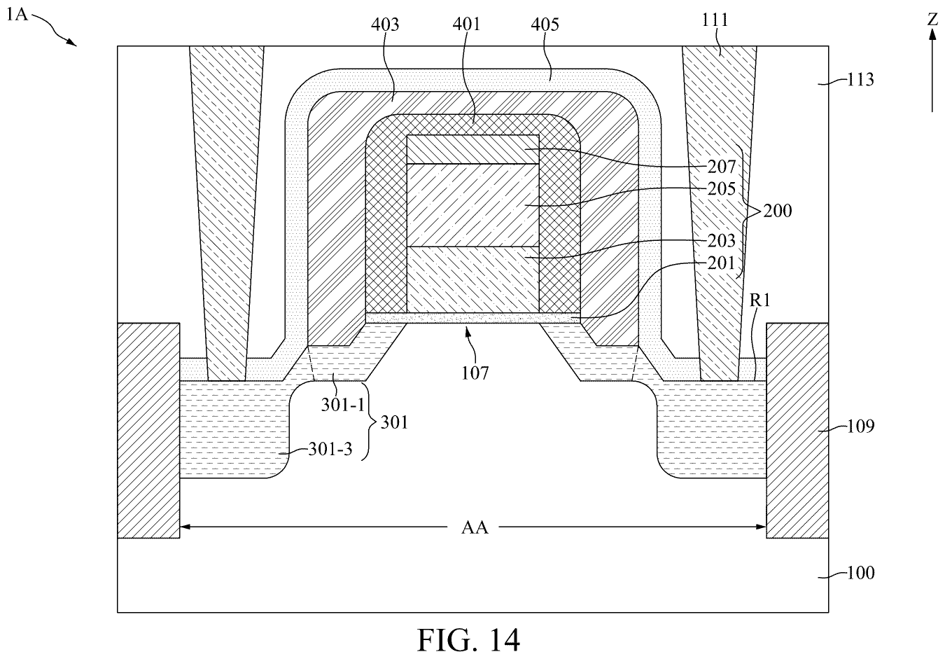

With reference to FIG. 14, the plurality of contacts 111 may be formed along the first insulating layer 113 and the outer space layer 405 and formed on the plurality of bulk doped portions 301-3, respectively and correspondingly. In some embodiments, the plurality of contacts 111 may be formed of, for example, doped polycrystalline silicon, doped polycrystalline germanium, doped polycrystalline silicon germanium, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

The employment of the plurality of lightly doped portions 301-1 formed by epitaxial growth with tailored dopant concentration, along with substrate 100 recessing, may reduce the drain-induced barrier lowering (DIBL). This mitigation may lead to enhanced on/off ratio and reduced random dopant fluctuations, resulting in enhanced performance of semiconductor device 1A.

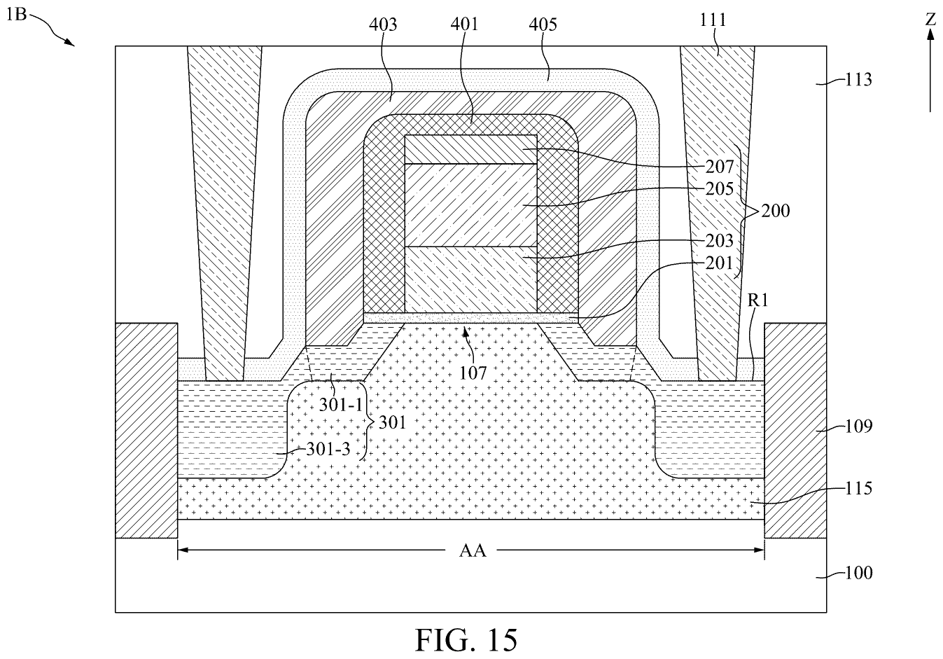

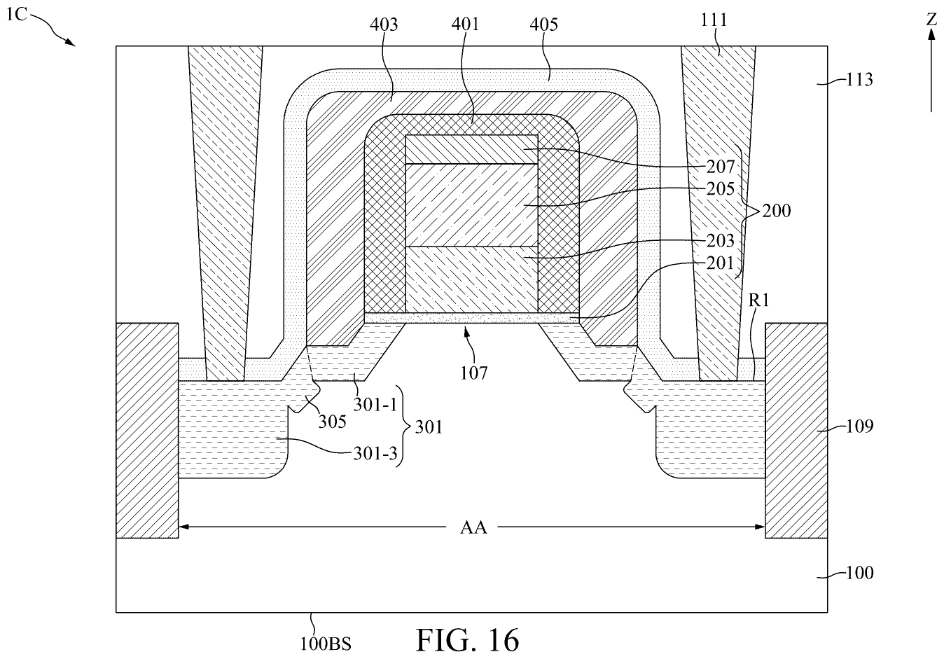

FIGS. 15 and 16 illustrate, in schematic cross-sectional view diagrams, semiconductor devices 1B and 1C in accordance with some embodiments of the present disclosure. With reference to FIG. 15, the semiconductor device 1B may

have a structure similar to that illustrated in FIG. 14. The same or similar elements in FIG. 15 as in FIG. 14 have been marked with similar reference numbers and duplicative descriptions have been omitted.

The semiconductor device 1B may include a well region 115. The well region 115 may be disposed in the active area AA. The plurality of impurity regions 301 and the channel region 107 may be disposed in the well region 115. In some embodiments, the well region 115 may have an electrical type which is opposite to the plurality of impurity regions 301.

With reference to FIG. 16, the semiconductor device 1C may have a structure similar to that illustrated in FIG. 14. The same or similar elements in FIG. 16 as in FIG. 14 have been marked with similar reference numbers and duplicative descriptions have been omitted.

The semiconductor device 1C may include a plurality of halo-junction layers 305. The halo-junction layer 305 may be disposed between the lightly doped portion 301-1 and the bulk doped portion 301-3. The halo-junction layer 305 may have the same electrical type as the lightly doped portion 301-1 and the bulk doped portion 301-3. The resistance of the channel region 107 may be further adjusted by the halo-junction layer 305.

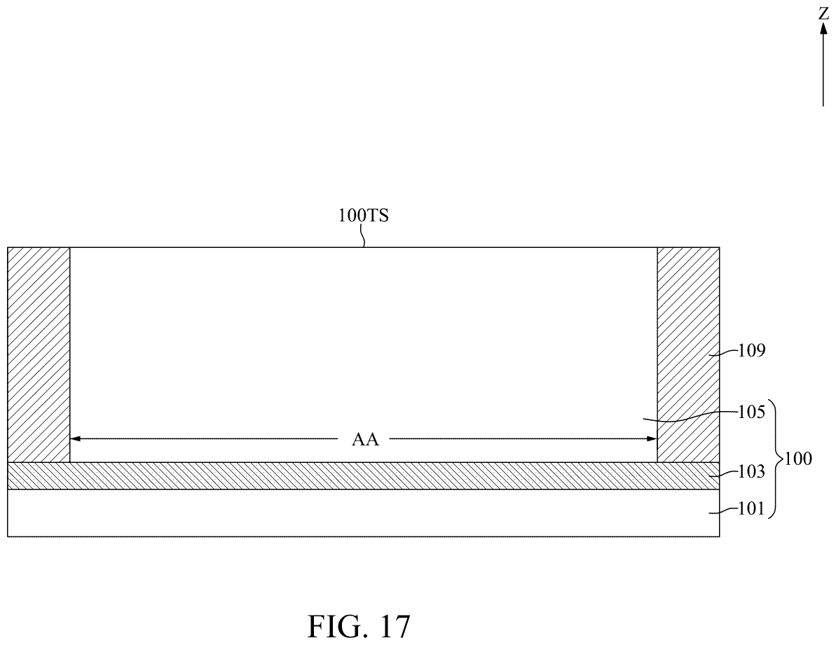

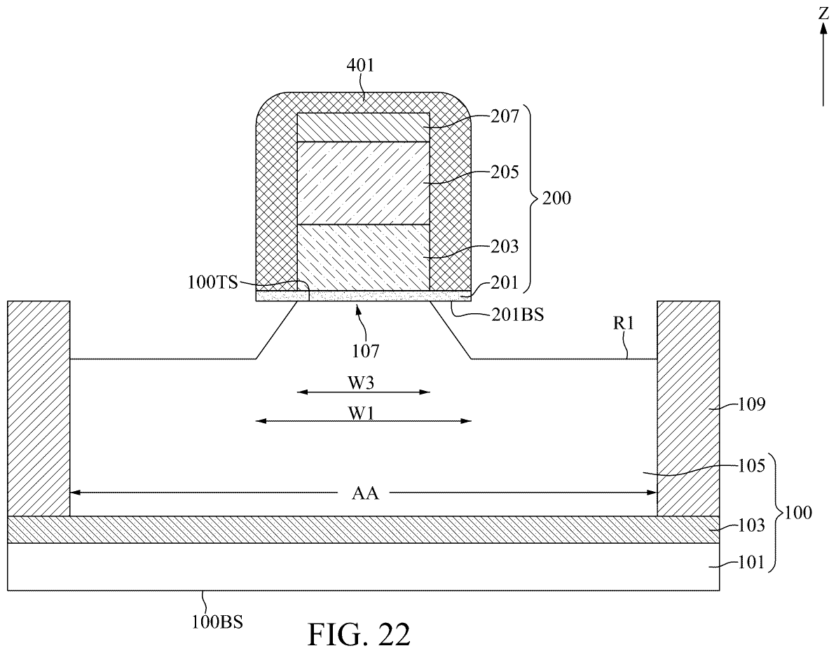

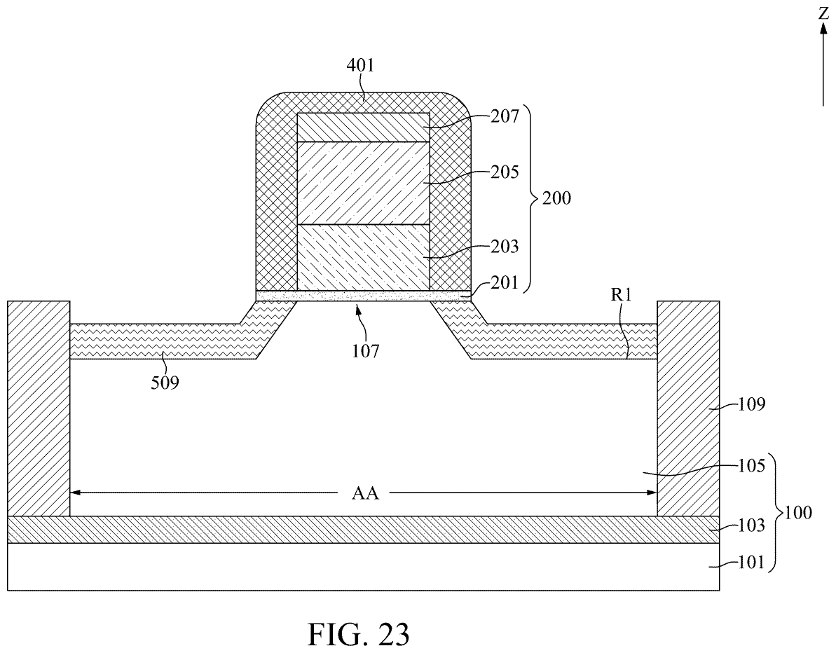

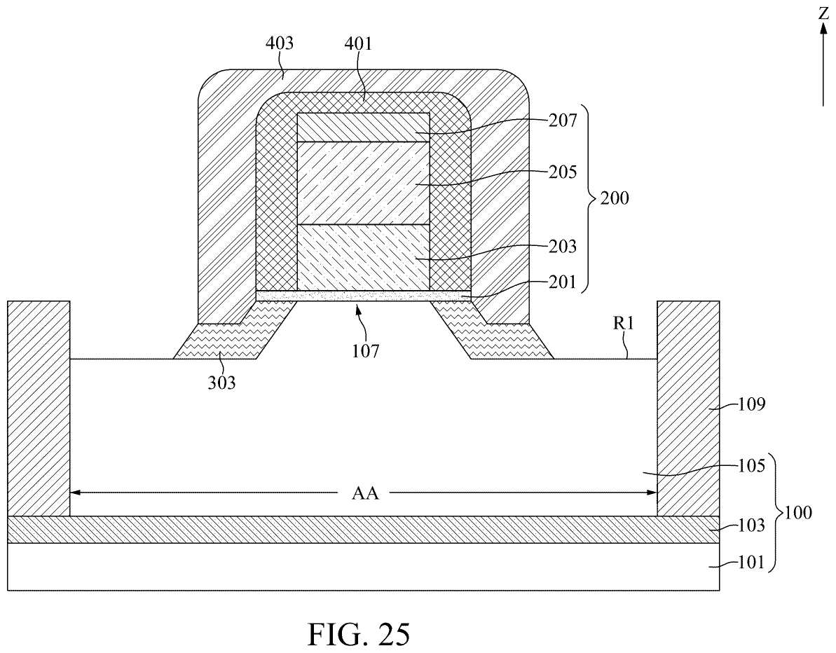

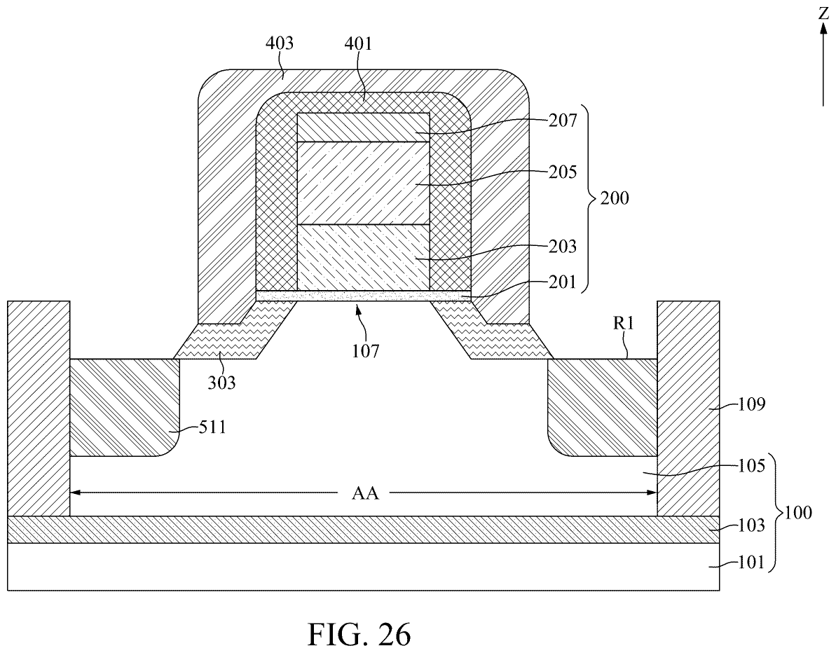

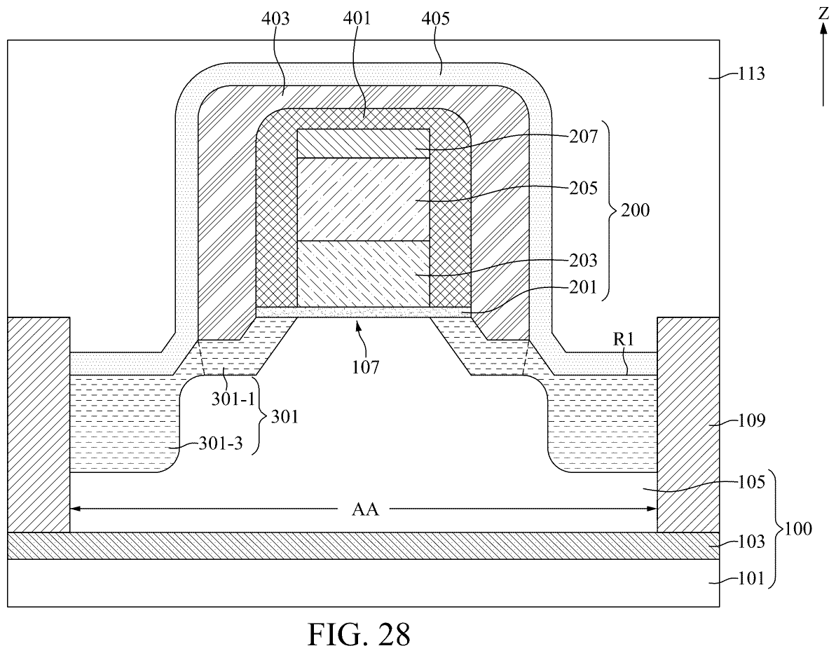

FIGS. 17 to 29 illustrate, in schematic cross-sectional view diagrams, a flow for fabricating the semiconductor device 1D in accordance with another embodiment of the present disclosure.

With reference to FIG. 17, the substrate 100 may include a semiconductor-on-insulator structure which consists of, from bottom to top, a bottom semiconductor layer 101, a buried insulating layer 103, and a top semiconductor layer 105. The bottom semiconductor layer 101 and the top semiconductor layer 105 may be formed of the same material as the substrate 100 illustrated in FIG. 2. The buried insulating layer 103 may be a crystalline or non-crystalline dielectric material such as an oxide and/or nitride. For example, the buried insulating layer 103 may be a dielectric oxide such as silicon oxide. For another example, the buried insulating layer 103 may be a dielectric nitride such as silicon nitride or boron nitride. For yet another example, the buried insulating layer 103 may include a stack of a dielectric oxide and a dielectric nitride such as a stack of, in any order, silicon oxide and silicon nitride or boron nitride. In some embodiments, the buried insulating layer 103 may have a thickness between about 10 nm and about 200 nm.

With reference to FIG. 17, the isolation layer 109 may be formed in the top semiconductor layer 105 and defining the active area AA with a procedure similar to that illustrated in FIG. 2, and descriptions thereof are not repeated herein.

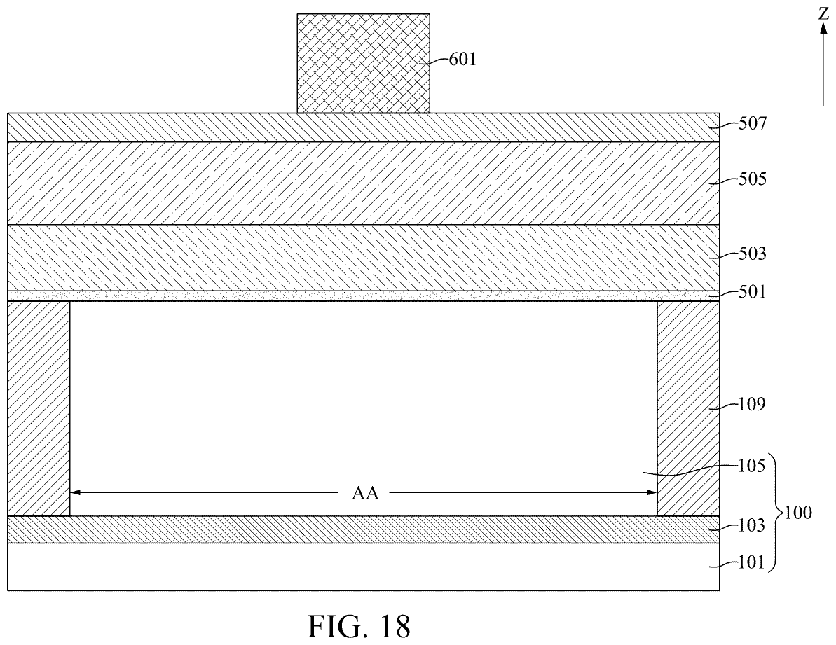

With reference to FIG. 18, the layer of first insulating material 501, the layer of first conductive material 503, the layer of second conductive material 505, the layer of second insulating material 507, and the first mask layer 601 may be sequentially formed on the top semiconductor layer 105 with a procedure similar to that illustrated in FIG. 3, and descriptions thereof are not repeated herein.

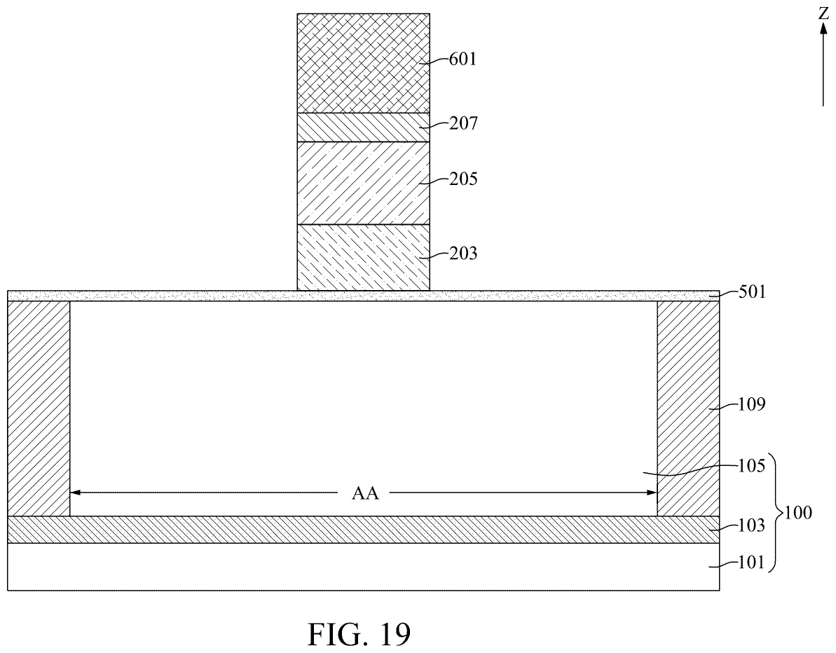

With reference to FIG. 19, the gate bottom conductive layer 203, the gate top conductive layer 205, and the gate capping layer 207 may be formed with a procedure similar to that illustrated in FIG. 4, and descriptions thereof are not repeated herein.

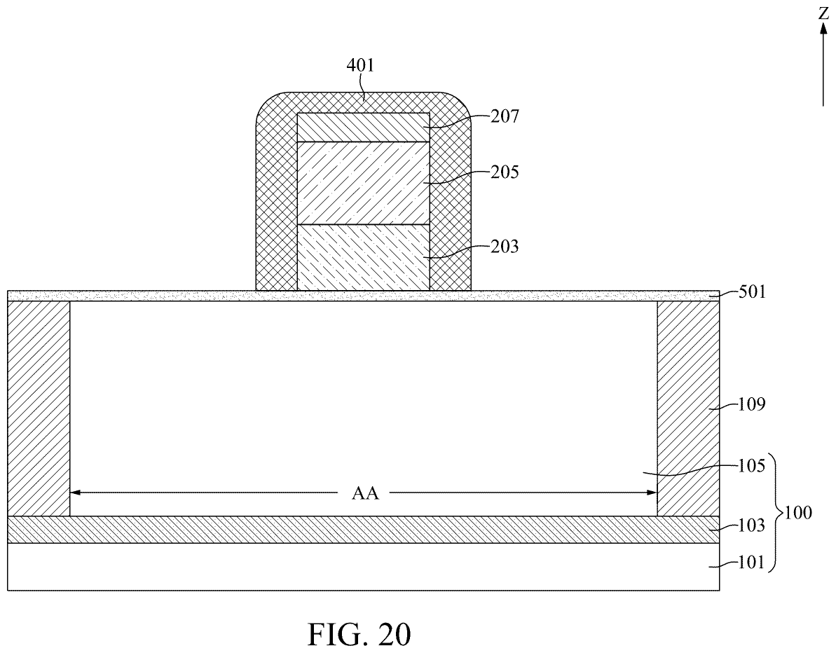

With reference to FIG. 20, the inner spacer layer 401 may be formed to cover the stack of the gate bottom conductive layer 203, the gate top conductive layer 205, and the gate capping layer 207 with a procedure similar to that illustrated in FIG. 5, and descriptions thereof are not repeated herein.

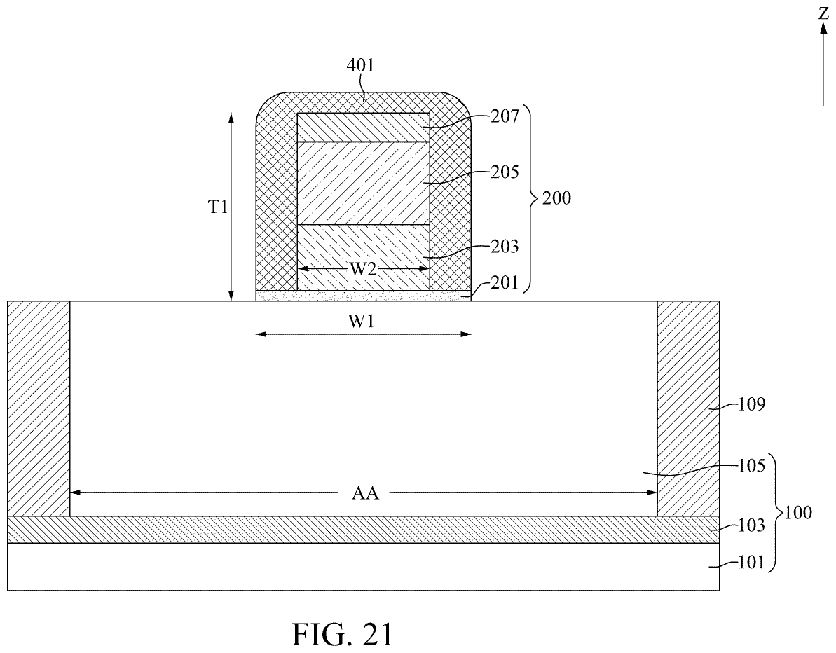

With reference to FIGS. 21 to 23, the gate dielectric layer 201, the plurality of recesses R1, the plurality of epitaxial layers 509 may be formed with a procedure similar to that illustrated in FIGS. 6 to 8, and descriptions thereof are not repeated herein.

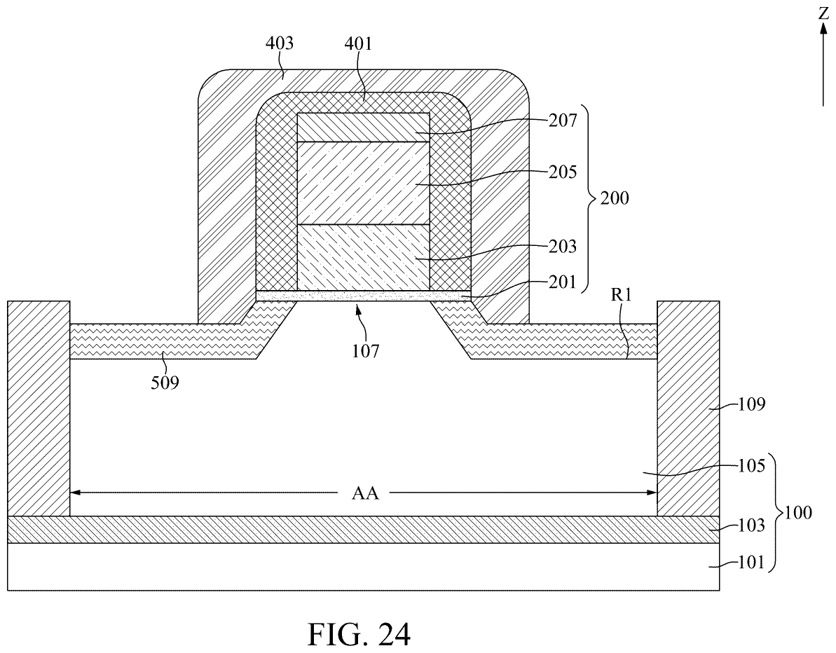

With reference to FIGS. 24 to 26, the middle spacer layer 403, the plurality of precursive layers 303, the plurality of pre-impurity regions 511 may be formed with a procedure similar to that illustrated in FIGS. 9 to 11, and descriptions thereof are not repeated herein.

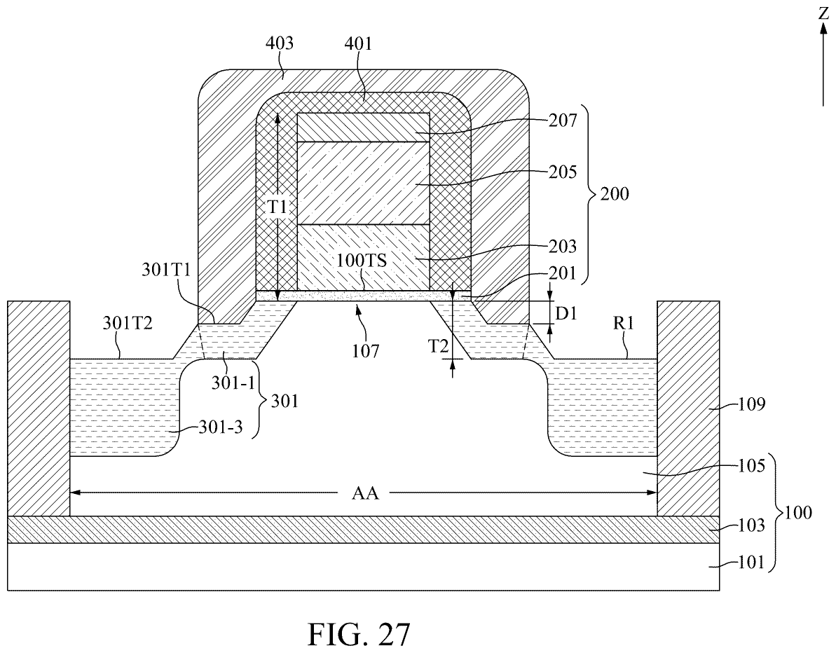

With reference to FIGS. 27 to 29, the plurality of impurity regions 301, the outer space layer 405, the first insulating layer 113, and the plurality of contacts 111 may be formed with a procedure similar to that illustrated in FIGS. 12 to 14, and descriptions thereof are not repeated herein.

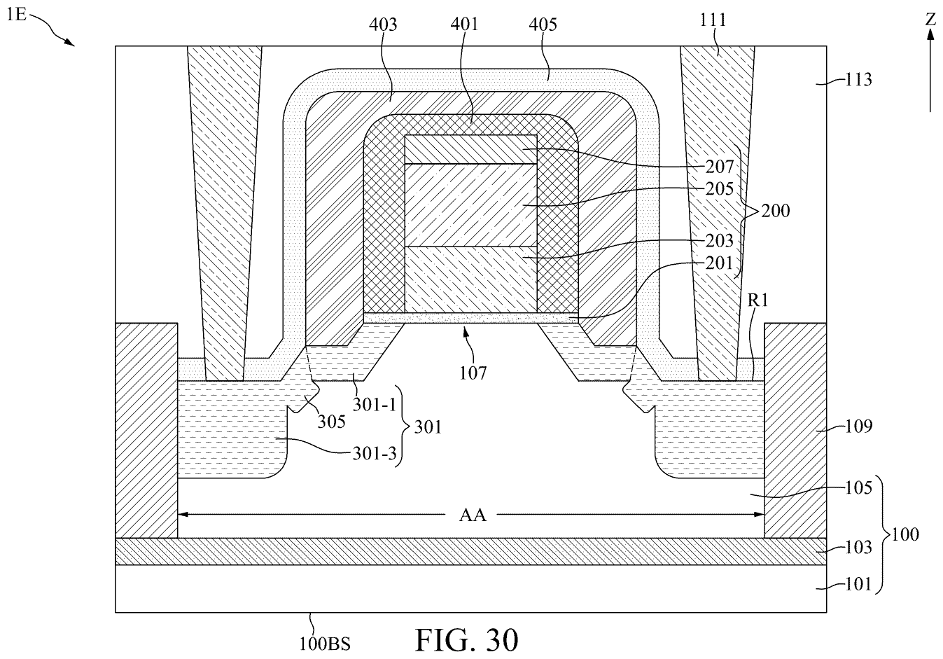

FIG. 30 illustrates, in a schematic cross-sectional view diagram, a semiconductor device 1E in accordance with another embodiment of the present disclosure.

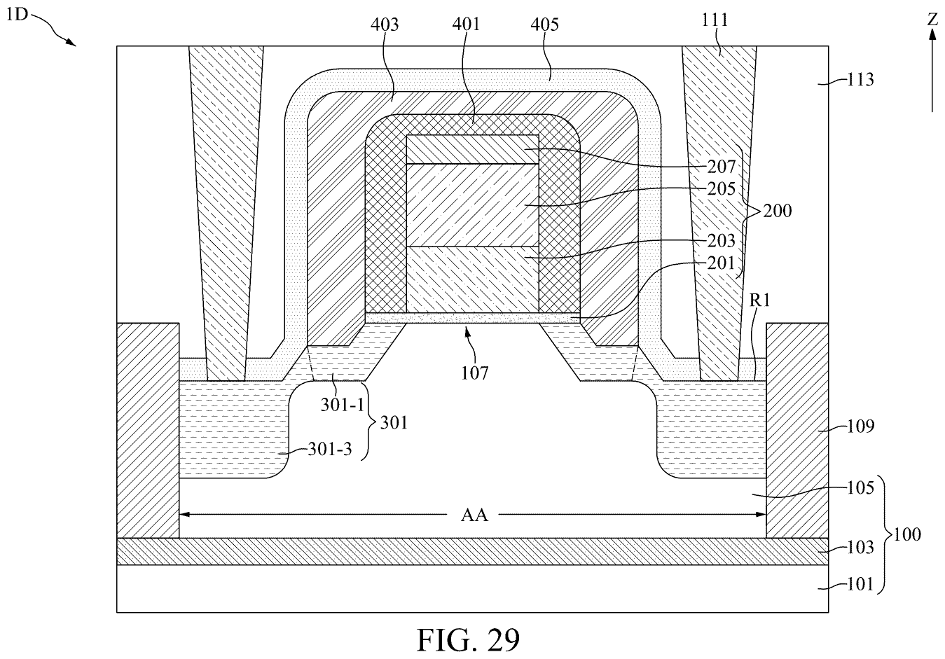

With reference to FIG. 30, the semiconductor device 1E may have a structure similar to that illustrated in FIG. 29. The same or similar elements in FIG. 30 as in FIG. 29 have been marked with similar reference numbers and duplicative descriptions have been omitted.

The semiconductor device 1E may include a plurality of halo-junction layers 305. The halo-junction layer 305 may be disposed between the lightly doped portion 301-1 and the bulk doped portion 301-3. The halo-junction layer 305 may have the same electrical type as the lightly doped portion 301-1 and the bulk doped portion 301-3. The resistance of the channel region 107 may be further adjusted by the halo-junction layer 305.

One aspect of the present disclosure provides a semiconductor device including a substrate; a plurality of recesses recessed from a top surface of the substrate defining a channel region between the plurality of recesses and adjacent to the top surface of the substrate; a gate structure positioned on the channel region; a plurality of impurity regions including a plurality of lightly doped portions positioned within the substrate and separated from each other with the channel region in between, and a plurality of bulk doped portions positioned within the substrate, and respectively and correspondingly connected to the plurality of lightly doped portions. A ratio of a thickness of the gate structure to a maximal depth between the top surface of the substrate and a top surface of the plurality of lightly doped portions is between about 7.00 and about 3.60.

Another aspect of the present disclosure provides a semiconductor device including a substrate including a bottom semiconductor layer, a buried insulating layer positioned on the bottom semiconductor layer, and a top semiconductor layer positioned on the buried insulating layer; a plurality of recesses recessed from a top surface of the top semiconductor layer defining a channel region between the plurality of recesses and adjacent to the top surface of the top semiconductor layer; a gate structure positioned on the channel region; a plurality of impurity regions including a plurality of lightly doped portions positioned within the top semiconductor layer and separated from each other with the channel region in between, and a plurality of bulk doped portions positioned within the top semiconductor layer, and respectively and correspondingly connected to the plurality of lightly doped portions. A ratio of a thickness of the gate structure to a maximal depth between the top surface of the substrate and a top surface of the plurality of lightly doped portions is between about 7.00 and about 3.60.

Another aspect of the present disclosure provides a method for fabricating a semiconductor device including providing a substrate; forming a gate structure on the substrate and forming an inner spacer layer covering the gate structure; recessing the substrate to form a plurality of recesses separated from each other with the gate structure in between; forming a plurality of epitaxial layers within the plurality of recesses; forming a middle spacer layer covering the inner spacer layer and masking portions of the plurality of epitaxial layers; partially removing the plurality of epitaxial layers to form a plurality of precursive layers and exposing the substrate; forming a plurality of pre-impurity regions in the substrate and connecting to the plurality of precursive layers; and performing a thermal treatment to turn the plurality of precursive layers into a plurality of lightly doped portions and the plurality of pre-impurity regions into a plurality of bulk doped portions. The plurality of lightly doped portions and the plurality of bulk doped portions together configure a plurality of impurity regions.

Due to the design of the semiconductor device of the present disclosure, the drain-induced barrier lowering (DIBL) may be reduced by the employment of the plurality of lightly doped portions 301-1 formed by epitaxial growth with tailored dopant concentration and the recessing of substrate 100. This mitigation may lead to enhanced on/off ratio and reduced random dopant fluctuations, resulting in enhanced performance of semiconductor device 1A.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate comprising:
a bottom semiconductor layer;
a buried insulating layer positioned on the bottom semiconductor layer; and
a top semiconductor layer positioned on the buried insulating layer;
a plurality of recesses recessed from a top surface of the top semiconductor layer defining a channel region between the plurality of recesses and adjacent to the top surface of the top semiconductor layer;
a gate structure positioned on the channel region; and
a plurality of impurity regions comprising:
a plurality of lightly doped portions positioned within the top semiconductor layer and separated from each other with the channel region in between; and
a plurality of bulk doped portions positioned within the top semiconductor layer, and respectively and correspondingly connected to the plurality of lightly doped portions;
wherein a ratio of a thickness of the gate structure to a maximal depth between the top surface of the substrate and a top surface of the plurality of lightly doped portions is between about 7.00 and about 3.60.

2. The semiconductor device of claim 1, further comprising an isolation layer positioned in the top semiconductor layer and defining an active area, wherein the plurality of recesses are positioned within the active area and the gate structure is positioned on the active area.

3. The semiconductor device of claim 2, wherein the gate structure comprises:
a gate dielectric layer positioned on the top semiconductor layer and between the plurality of recesses;
a gate bottom conductive layer positioned on the gate dielectric layer;
a gate top conductive layer positioned on the gate bottom conductive layer; and
a gate capping layer positioned on the gate top conductive layer.

4. The semiconductor device of claim 3, further comprising an inner spacer layer positioned on the top semiconductor layer and covering the gate structure.

5. The semiconductor device of claim 4, further comprising a middle spacer layer positioned on the plurality of lightly doped portions and covering the inner spacer layer.

6. The semiconductor device of claim 5, further comprising an outer space layer positioned on the plurality of bulk doped portions and covering the middle spacer layer.

7. The semiconductor device of claim 6, wherein the inner spacer layer and the outer space layer comprise the same material.

8. The semiconductor device of claim 6, wherein the middle spacer layer comprises silicon oxide.

9. The semiconductor device of claim 1, further comprising a plurality of halo-junction layers positioned within the top semiconductor layer and respectively positioned between the plurality of lightly doped portions and the plurality of bulk doped portions.

10. The semiconductor device of claim 1, wherein a ratio of the thickness of the gate structure to a thickness of the plurality of lightly doped portions is between about 3.50 and about 2.20.
